(19) United States
(12) Patent Application Publication
(10) Pub. No.: US 2005/0189088 A1
(43) Pub. Date: Sep. 1, 2005

(54) Circulation structure of heat dissipation device

(76) Inventors: Chin Wen Wang, Pingjhen City (TW); Ching Chung Wang, Pingjhen City (TW); Pei Choa Wang, Pingjhen City (TW)

Correspondence Address: Yi-Wen Tseng, 4331 Stevens Battle Lane, Fairfax, VA, 22033, US

(21) Appl. No.: 10/785,958

(22) Filed: Feb. 26, 2004

(51) Int. Cl. H05K 7/20

(52) U.S. Cl. 165/80.3; 361/704; 165/121; 361/697

(57) ABSTRACT

A heat dissipation device includes a heat conducting plate, a fin set, a mask enclosing the fin set, and a fan. The fin set is located on the heat conducting plate. The mask has an air inlet formed on a front side and an air outlet formed on a top surface thereof. The fan is mounted over the top surface and with respect to the air outlet to circulate airflow from the air inlet through the fin set to the air outlet. Moreover, a room inside the mask is divided into a lower passage continued with an upper passage, the air inlet is formed as one end of the lower passage, and the other end of the lower passage is connected to the upper passage. Accordingly, a circulation structure of the heat dissipation device is provided to rapidly dissipate heat generated by the electronic components. Such that, the heat dissipation performance is improved.

### BACKGROUND OF THE INVENTION

The present invention relates to a circulation structure of a heat dissipation device, and more particular, to a heat dissipation device for an electronic component with an enhanced heat circulation structure to perform efficient heat dissipation.

Conventional heat dissipation device 10a for a central processing unit (CPU) 20a is shown as FIG. 1. The heat dissipation device 10a includes a conducting plate 1a attached to the CPU 20a, and a set of heat dissipating fins 2a located on the conducting plate 1a. The fin set 2a is constructed by a plurality of fins 21a vertically and uniformly extended from the conducting plate 1a. Moreover, a mask 3a encloses the fin set 2a and a fan 4a is mounted above the mask 3a to circulate air so that the heat dissipated from the fins 21a is taken away.

However, in conventional circulation structure of the above-mentioned heat dissipation device 10, the heat generated by the CPU 20a is delivered from the conducting plate 1a to the fins 21a for dissipation. Meanwhile, the fan 4a circulates surrounding air through the fins 21a. Within the enclosure of the mask 3a, the circulating air and the dissipating heat may be improperly mixed. Such that, the heat within the mask 3a may not be blown out, or even worse, the circulating air may blow the heat back to CPU 20a. Therefore, the heat dissipation may not be efficiently performed.

To resolve the problems caused by the conventional circulation structure of the heat dissipation device as described above, the Applicant, with many years of experience in this field, has developed an improved circulation structure of the heat dissipation device as described as follows.

### BRIEF SUMMARY OF THE INVENTION

The present invention provides a circulation structure of a heat dissipation device to rapidly dissipate heat generated by the electronic components. Such that the heat dissipation performance is improved.

According to the present invention, the heat dissipation device includes a heat conducting plate, a fin set, a mask enclosing the fin set, and a fan. The fin set is located on the heat conducting plate. The mask has an air inlet formed on a front side and an air outlet formed on a top surface thereof. The fan is mounted over the top surface and with respect to the air outlet to circulate airflow from the air inlet through the fin set to the air outlet. Moreover, a room inside the mask is divided into a lower passage continued with an upper passage, the air inlet is formed as one end of the lower passage, and the other end of the lower passage is connected to the upper passage.

These and other objectives of the present invention will become obvious to those of ordinary skill in the art after reading the following detailed description of preferred embodiments.

It is to be understood that both the foregoing general description and the following detailed description are exemplary, and are intended to provide further explanation of the invention as claimed.

### BRIEF DESCRIPTION OF THE DRAWINGS

These, as well as other features of the present invention, will become apparent upon reference to the drawings wherein:

FIG. 1 shows a perspective view of a conventional heat dissipation device;

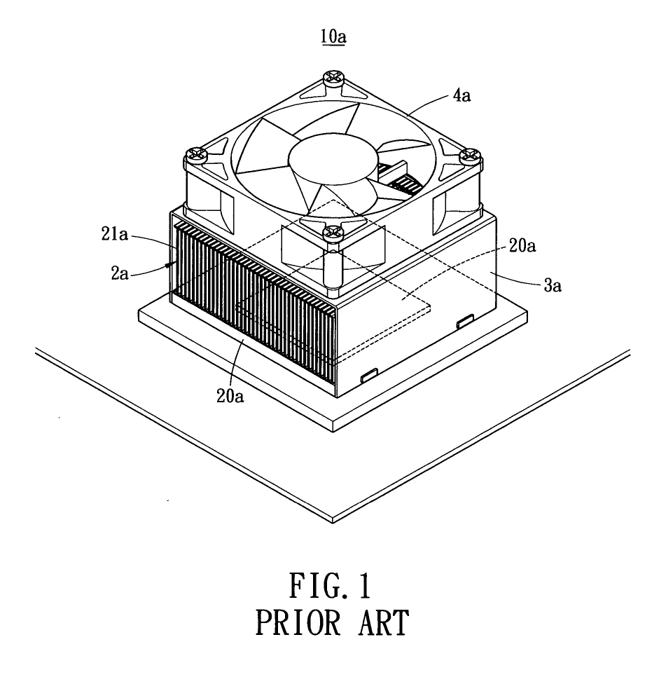

FIG. 2 shows an exploded view of a heat dissipation device provided by the present invention;

FIG. 3 shows a perspective view of the heat dissipation device;

FIG. 4 shows a cross-sectional view of the heat dissipation device;

FIG. 5 shows anther cross-sectional view of the heat dissipation device;

FIG. 6 shows an application of the heat dissipation device used for the CPU;

FIG. 7 shows an exploded view of the heat dissipation device according to another preferred embodiment; and

FIG. 8 shows a cross-sectional view of the heat dissipation device in FIG. 7.

### DETAILED DESCRIPTION OF THE INVENTION

Reference will now be made in detail to the preferred embodiments of the present invention, examples of which are illustrated in the accompanying drawings. Wherever possible, the same reference numbers are used in the drawings and the description to refer to the same or like parts.

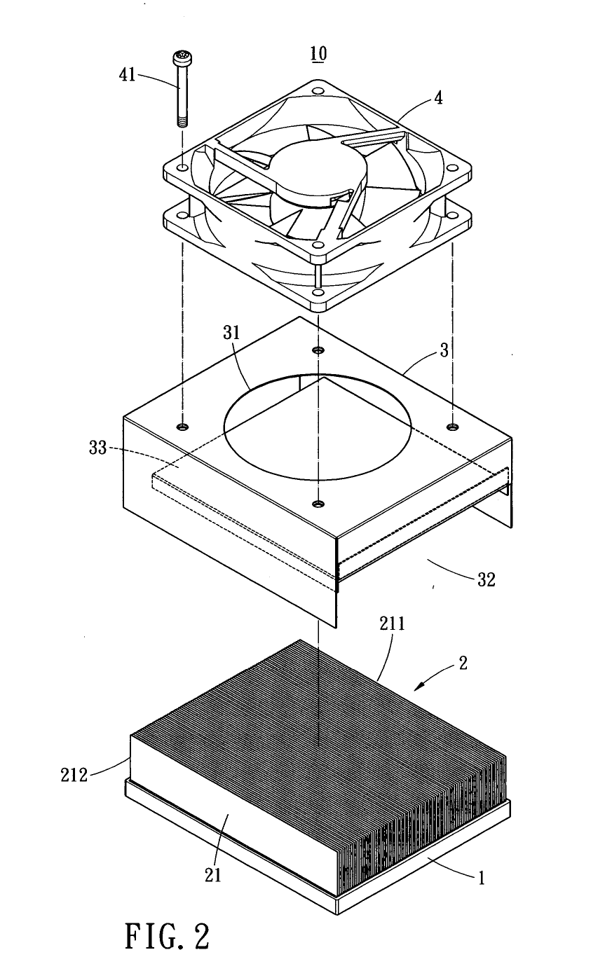

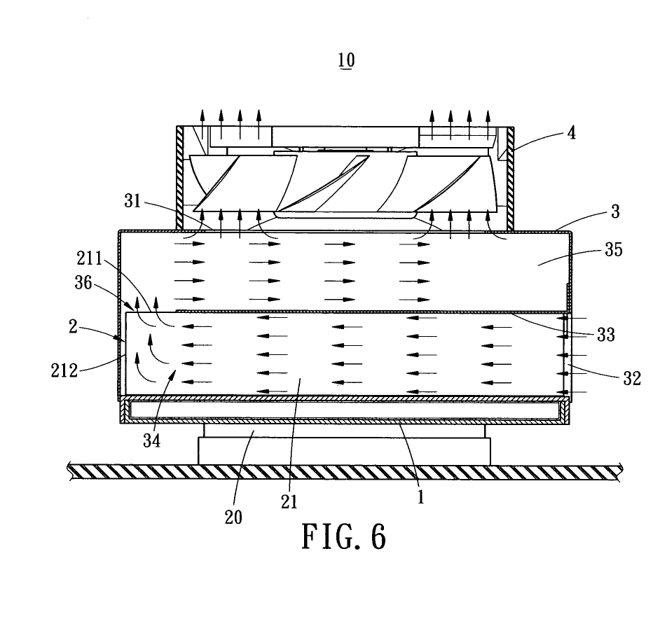

Referring to FIG. 2, the present invention provides a heat dissipation device 10 to dissipate heat generated by the central processing unit (CPU). The heat dissipation device 10 includes a heat conducting plate 1 mounted on a CPU 20 (as shown in FIG. 6). The heat conducting plate 1 has a square shape and is normally larger than CPU 20. Preferably, the heat conducting plate 1 is made by the copper material.

A fin set 2 is formed on the heat conducting plate 1. The fin set 2 includes a plurality of fins 21 to be vertically and uniformly furnished on the heat conducting plate 1. Each fin 21 is formed as a rectangular plate defined with a long side 211 and short side 212. Preferably, the fins 21 are made by the aluminum material. Moreover, a mask 3 is used to enclose the fin set 2, and a fan 4 is mounted over the mask 3. An opening 31 corresponding to the location of the fan 4 is formed on a top surface of the mask 3 to be as an air outlet.

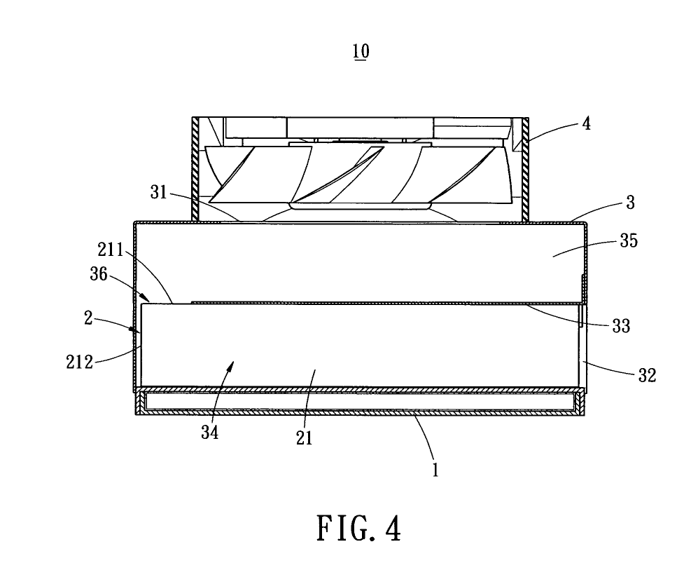

Furthermore, another opening 32 corresponding to the short side 212 of each fin 21 is formed on a front side of the mask 3 to be as an air inlet. In this preferred embodiment, a board 33 is transversally mounted in a room inside the mask 3, such that the room is divided into a lower circulation passage 34 continued with an upper circulation passage 35 (as shown in FIG. 4). The fin set 2 is located inside the lower circulation passage and the inlet opening 32 is formed with respect to the lower circulation passage 34. A connection 36 of the lower and the upper circulation passages 34, 35 is formed at a distal end of the board 33 away from the inlet opening 32. Therefore, the inlet opening 32 is formed as one end of the lower circulation passage 34, and the other end of the lower circulation passage 34 is formed as the connection 36 to the upper circulation passage 35. As such, the air circulating by the fan 4 will flow from the outlet opening 32, through the fins 21 in the lower circulation passage 34, following into the upper circulation passage 35, and then out of the outlet opening 31 so as to take away heat generated by CPU 20.

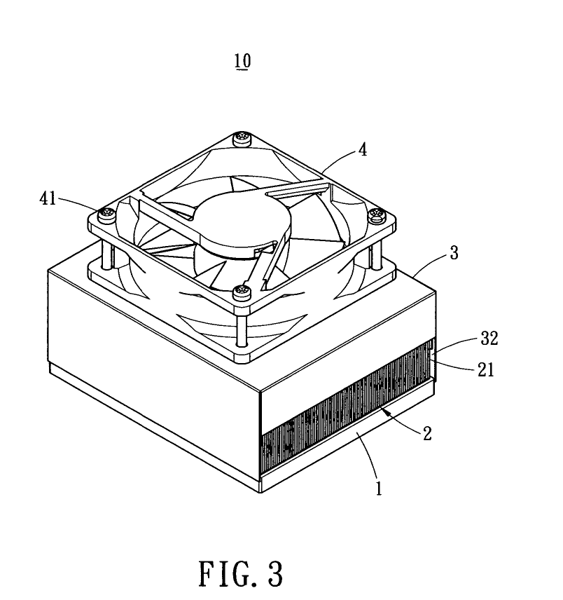

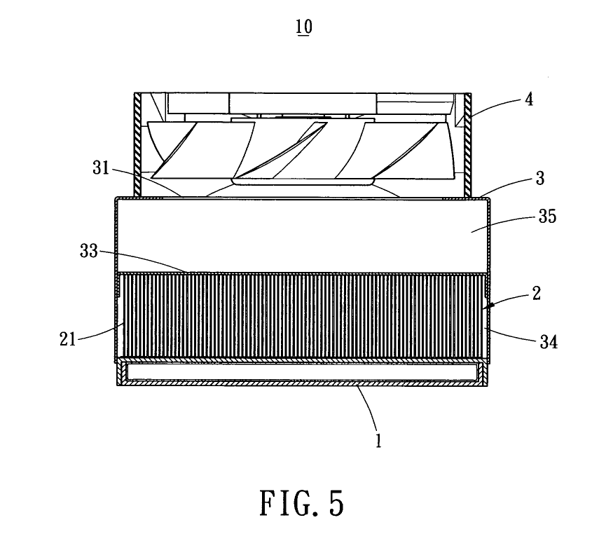

Referring to FIGS. 3 to 5, the fin set 2 is first mounted on the heat conducting plate 1, and the mask 3 is then furnished to have fin set 2 enclosed inside the lower circulation passage 3 with the inlet opening 32 corresponding to the short side of each fin 21. Next, a fastening member 41 is used to mount the fan 4 on the top of the mask 3 to complete the assembly of the heat dissipation device 10 as shown in FIG. 3.

In FIG. 6, after the dissipation device 10 is mounted to CPU 20, the heat generating by CPU 20 is delivered through the heat conducting plate 1 to the fin set 2. Meanwhile, under the circulation of the fan 4, the environmental air (indicated by arrows) flows from the inlet opening 32 into the lower circulation passage 34. Then, the air flows between the fins 21 to the connection 36. Thereafter, the heat is dissipated with the air via the upper circulation passage 35 to be blown out of the fan 4 from the outlet opening 31.

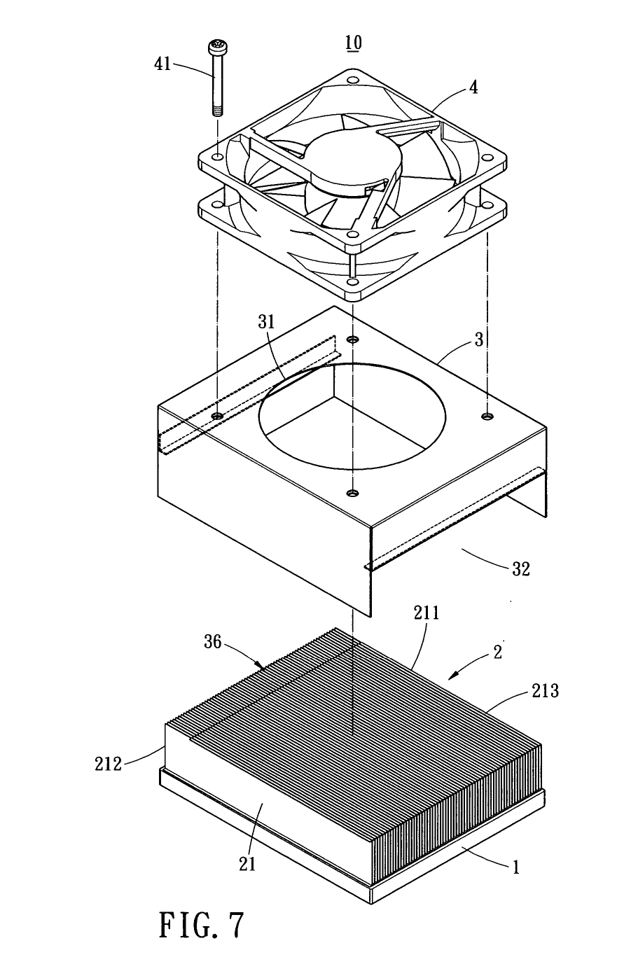

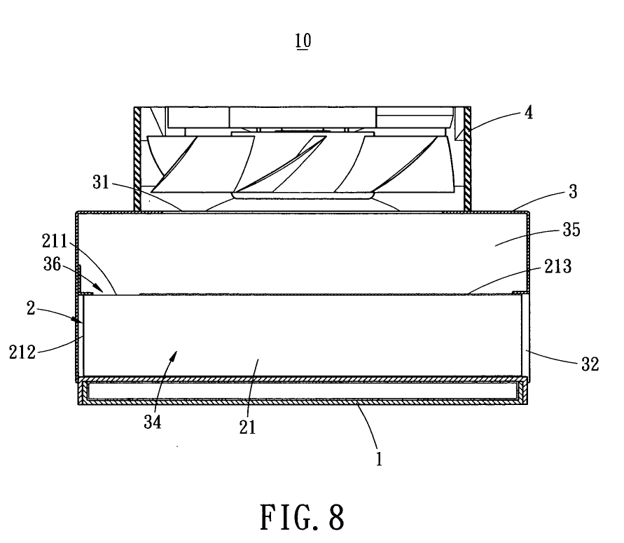

In another preferred embodiment of the present invention, as shown in FIGS. 7 and 8, the room inside the mask 3 is divided by the fins 21 themselves without installing the transverse board 33. Each fin 21 includes a partial folding edge 213 formed on a top surface thereof, so that after the fin set 2 is constructed on the heat conducting plate 1 by aligning the fins 21 one by one, the folding edges 213 are connected to each other to divide the room into the lower circulation passage 34 continued with the upper circulation passage 35 by the connection 36, similar to the above-mentioned circulation structure.

In this present invention, the fan 4 circulates the air from the inlet opening 32 to the outlet opening 31 via the divided but continuous lower and upper circulation passages 34, 35. Moreover, the fin set 2 is merely located in the lower circulation passage 34. Therefore, when the circulating air flows through the fins 21 to take away the heat, the heat is efficiently followed with the air circulation into the upper circulation passage 35 to be blown out to the environment. On the other hand, the heat will not be blown back to CPU 20 or other adjacent electronic components. As such, according to the circulation structure of the present heat dissipation device 10, an improved heat dissipation performance is achieved.

This disclosure provides exemplary embodiments of the present invention. The scope of this disclosure is not limited by these exemplary embodiments. Numerous variations, whether explicitly provided for by the specification or implied by the specification, such as variations in shape, structure, dimension, type of material or manufacturing process may be implemented by one of skill in the art in view of this disclosure.

1. A heat dissipation device, comprising:
a heat conducting plate;
a fin set located on the heat conducting plate;
a mask enclosing the fin set, having an air inlet formed on a front side, and an air outlet formed on a top surface thereof; and
a fan mounted over the top surface and with respect to the air outlet to circulate airflow from the air inlet through the fin set to the air outlet,
wherein a room inside the mask is divided into a lower passage continued with an upper passage, the air inlet is formed as one end of the lower passage, and the other end of the lower passage is connected to the upper passage.

2. The device of claim 1, wherein the heat conducting plate is made of a copper material.

3. The device of claim 1, wherein the fin set comprises a plurality of fins vertically and uniformly formed on the heat conducting plate.

4. The device of claim 3, wherein the fins are made of an aluminum material.

5. The device of claim 3, wherein each fin comprises a folding edge on a top surface thereof, such that after the fin set is constructed, each folding edge is connected to each other to divide the room inside the mask into the lower and the upper passages.

6. The device of claim 1, further comprising a board transversally installed inside the mask to divide the room inside the mask into the lower and the upper passages.
